(19) United States
(12) Patent Application Publication
(10) Pub. No.: US 2014/0285177 A1
(43) Pub. Date: Sep. 25, 2014

(54) MOBILE CURRENT MEASUREMENT EQUIPMENT, CURRENT MEASUREMENT TERMINAL AND CURRENT MEASUREMENT METHOD

(71) Applicant: Samsung Electronics Co., Ltd., Suwon-si (KR)

(72) Inventors: Youjin KIM, Suwon-si (KR); Mihyun LEE, Suwon-si (KR); Jeongnam CHEON, Suwon-si (KR)

(73) Assignee: Samsung Electronics Co., Ltd., Suwon-si (KR)

(21) Appl. No.: 14/221,769

(22) Filed: Mar. 21, 2014

(30) Foreign Application Priority Data
Mar. 21, 2013 (KR) 10-2013-0030276

(51) Int. Cl. G01R 19/00

(52) U.S. Cl. CPC G01R 19/0092
USPC 324/76.11

(57) ABSTRACT

A mobile current measurement apparatus, a current measurement terminal, and a current measurement method are provided. More particularly, the present disclosure provides a mobile current measurement apparatus, a current measurement terminal, and a current measurement method capable of measuring a current of a Device-Under-Test (DUT) by using a wireless short distance communication. The method of measuring a current by a current measurement apparatus includes detecting a voltage converted from a current of a device-under-test, compensating the detected voltage by using a voltage offset generated by an amplifier of the current measurement apparatus, and measuring the current of the device-under-test based on the compensated voltage.

### CROSS-REFERENCE TO RELATED APPLICATION(S)

This application claims the benefit under 35 U.S.C. §119(a) of a Korean patent application filed on Mar. 21, 2013 in the Korean Intellectual Property Office and assigned Serial number 10-2013-0030276, the entire disclosure of which is hereby incorporated by reference.

### TECHNICAL FIELD

The present disclosure relates to a mobile current measurement apparatus, a current measurement terminal, and a current measurement method. More particularly, the present disclosure relates to a mobile current measurement apparatus, a current measurement terminal, and a current measurement method capable of measuring a current of a Device-Under-Test (DUT) by using a wireless short distance communication while moving.

### BACKGROUND

A current measurement apparatus of the related art measures a current of a Device-Under-Test (DUT) by using a current sensing resistor method. The current sensing resistor method measures a voltage difference generated by a current flowing through both ends of a sensing resistance by using an OPerational AMPlifier (OP AMP), and calculates the current through the measured voltage difference.

Such a current measurement apparatus has a wired connection with an apparatus for displaying the measurement result, e.g., an oscilloscope, which imposes restrictions on mobility, such that a desired DUT cannot be measured in a desired location. In addition, when the current measurement apparatus of the related art attempts to wirelessly transmit the measurement result to another apparatus, the increase of a sampling speed of the current measurement is limited due to a bottleneck.

Further, the current measurement apparatus of the related art just provides a current value or a current graph as the measurement result, but it has no analysis function and data storing function, such that a user should directly watch the result with the naked eye and intuitively determine the result.

Furthermore, in the current measurement apparatus of the related art, the OP AMP has its own voltage offset generated by the manufacturing process, such that an error occurs in an output end as much as the voltage offset, and such error causes deviation of the total measurement result. In the related art, to address this problem, a method of power compensation or a method of increasing a current sensing resistor value is used.

The method of power compensation is a method of adding a power compensation circuit to reduce the error. However, it has a problem of generating an addition error for an added reference power, and increasing of price and size of equipment due to the addition of expensive and high stability circuit components and a calibration function.

The method of increasing a current sensing resistor value of the related art has a problem in that the voltage supplied to the DUT is decreased to affect the performance of the measurement when measuring the current consumption of the DUT which uses a low voltage such as a portable terminal. Therefore, a need exists to develop a current measurement apparatus which is able to address the above problem and have mobility.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a mobile current measurement apparatus employing an algorithm which compensates a voltage offset due to an amplifier in software.

Another aspect of the present disclosure is to provide a mobile current measurement apparatus, a current measurement terminal, and a current measurement method capable of sampling a measurement result according to a wireless short distance communication period, transmitting the sampling result to other terminal by using a wireless short distance communication, and displaying the measurement result in the current measurement terminal

Another aspect of the present disclosure is to provide a current measurement terminal which records and notifies of an occurrence of abnormal current to a user when the abnormal current occurs in the terminal based on the measurement result received from a mobile current measurement apparatus.

In accordance with an aspect of the present disclosure, a method of measuring a current by a current measurement apparatus is provided. The method includes detecting a voltage converted from a current of a device-under-test, compensating the detected voltage by using a voltage offset generated by an amplifier of the current measurement apparatus, and measuring the current of the device-under-test based on the compensated voltage.

In accordance with another aspect of the present disclosure, a method of measuring a current is provided. The method includes detecting a request for measuring a current of a device-under-test, receiving a current measurement result for the device-under-test from a current measurement apparatus in response to the request, and displaying the received current measurement result.

In accordance with another aspect of the present disclosure, a current measurement apparatus is provided. The current measurement apparatus includes a measurement circuit unit configured to detect a voltage converted from a current of a device-under-test, a controller configured to compensate the detected voltage by using a voltage offset generated by an amplifier of the current measurement apparatus, and measure the current of the device-under-test based on the compensated voltage, and a storage unit configured to store the measured current under control of the controller.

In accordance with another aspect of the present disclosure, a current measurement terminal is provided. The current measurement terminal includes a communication unit configured to perform a wireless communication with a current measurement apparatus, a display unit configured to output data, and a controller configured to control the communication unit to receive a current measurement result for a device-under-test from the current measurement apparatus, and control the display unit to display the received current measurement result.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating a configuration of a current measurement apparatus according to an embodiment of the present disclosure;

FIG. 2 is a block diagram illustrating a measurement circuit unit of a current measurement apparatus according to an embodiment of the present disclosure;

FIG. 3 is a block diagram illustrating a configuration of a current measurement terminal according to an embodiment of the present disclosure;

FIG. 4 is a flowchart illustrating a current measurement method of a current measurement apparatus according to an embodiment of the present disclosure;

FIG. 5 is a flowchart illustrating a method of transmitting a measurement result to an external device by a current measurement apparatus according to an embodiment of the present disclosure; and

FIG. 6 is a flowchart illustrating a current measurement method of a current measurement terminal according to an embodiment of the present disclosure.

The same reference numerals are used to represent the same elements throughout the drawings.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Embodiments of the present disclosure may be applied to a control of a current measurement apparatus and a current measurement terminal that measure a current consumption of a Device-Under-Test (DUT).

The current measurement terminal may include all terminals to which a short distance wireless communication may be applied, as well as a general electronic terminal such as a Smart Phone, a Portable Terminal, a Mobile Terminal, a Personal Digital Assistant (PDA), a Portable Multimedia Player (PMP), a Note Pad, a Wibro terminal, a Tablet Personal Computer (PC), and the like.

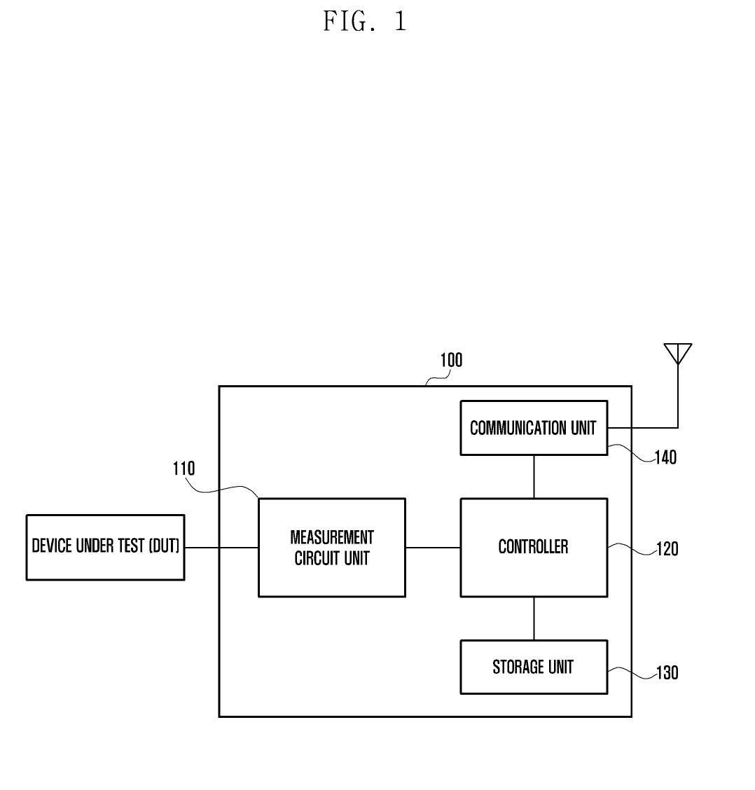

FIG. 1 is a block diagram illustrating a configuration of a current measurement apparatus according to an embodiment of the present disclosure.

Referring to FIG. 1, the current measurement apparatus 100 according to an embodiment of the present disclosure may include a measurement circuit unit 110, a controller 120, a storage unit 130, and a communication unit 140.

The measurement circuit unit 110 may convert a current of a DUT, which is a measurement target, into a voltage to detect. To this end, the measurement circuit unit 110 may be connected with the DUT through a connector, a cable, or the like.

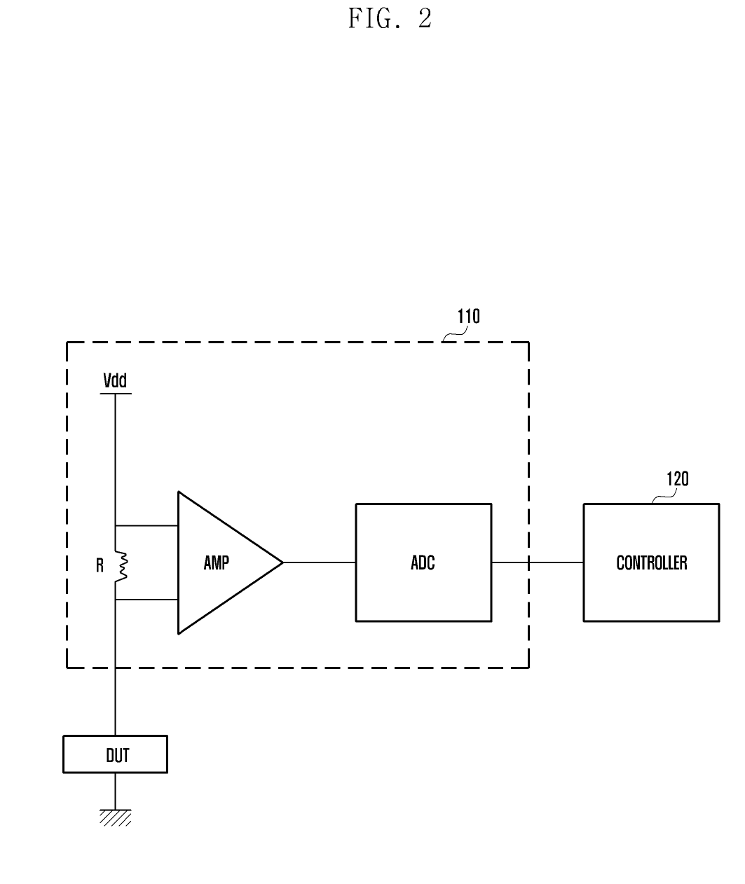

The measurement circuit unit 110 may be configured with a circuit as illustrated in FIG. 2.

FIG. 2 is a block diagram illustrating a measurement circuit unit of a current measurement apparatus according to an embodiment of the present disclosure.

Referring to FIG. 2, the measurement circuit unit 110 may include a resistor.

The resistor may be connected with a voltage supplied to the current measurement apparatus 100 and the DUT, and convert the current of the DUT into a voltage. To this end, the resistor may be electrically connected with a voltage supplied to the measurement circuit unit 110 and the DUT.

The resistor may be connected with an amplifier. The ports of the amplifier (+ port and − port) are connected with ends of the resistor respectively. Accordingly, the amplifier may receive a voltage difference of the resistor as an input voltage, and output an output voltage according to the input voltage depending on a characteristic of the amplifier.

An Analog Digital Converter (ADC) may be connected with the output end of the amplifier. The ADC may convert the output voltage of the amplifier which is an analog type into a digital signal to send to the controller 120 so that the controller 120 may process the signal.

In addition, the measurement circuit unit 110 may include a ground port to process an end of the circuit to be electrically grounded, and at least one resistor to control an amplification ratio of the amplifier, and not limited to the above described configuration.

The controller 120 may measure the current based on the output voltage received from the measurement circuit unit 110. In more detail, the controller 120 may calculate and measure the current of the DUT based on the voltage supplied to the current measurement apparatus 100, the magnitude of the resistor provided in the measurement circuit unit 110, and the received output voltage of the amplifier. For instance, the controller 120 may determine the input voltage, i.e., the voltage measured in the resistor based on the output voltage by using the characteristic of the amplifier, and may calculate the current of the DUT by using the determined voltage and the magnitude of the resistor.

In an embodiment of the present disclosure, the controller 120 may compensate the voltage detected in the measurement circuit unit 110 by using a voltage offset due to the amplifier. The amplifier may output a certain voltage even when a voltage is not applied to the measurement circuit unit 110 because of its own resistor, which is called as a voltage offset. The voltage offset generates an error in the voltage detected in the measurement circuit unit 110, thereby generating an error of the current of the DUT. Accordingly, the controller 120 may compensate the voltage detected in the measurement circuit unit 110 as much as the voltage offset, such that the error for the current may be decreased or removed.

In more detail, the measurement circuit unit 110 may send the voltage output from the amplifier to the controller 120 when the measurement circuit unit 110 is not connected to the DUT and the current does not flow in the resistor. The controller 120 may store the received voltage as an offset voltage of the amplifier, i.e., a first offset voltage, a first compensation voltage, or the like.

In addition, the measurement circuit unit 110 may send the voltage output from the amplifier to the controller 120 when the measurement circuit unit 110 is not connected to the DUT and a reference current (e.g., 1 mA) flows in the resistor. The controller 120 may calculate an error between the received voltage and the voltage which should be measured theoretically by the reference current. In addition, the controller 120 may store a difference of the error value and the first offset voltage in the storage 130 as the offset voltage during the operation of the amplifier, i.e., a second offset voltage, a second compensation voltage, or the like.

Thereafter, the measurement circuit unit 110 may send the voltage output from the amplifier to the controller 120 when the measurement circuit unit 110 is connected to the DUT and the current is supplied to the current measurement apparatus 100. The controller 120 may measure an accurate current by compensating the received voltage by using the first offset voltage and the second offset voltage.

In an embodiment of the present disclosure, the controller 120 may perform a sampling for at least one measured current. The controller 120 may transmit a measurement result including at least one measured current. To this end, at least one measured current may be sampled in response to a transmission period of the wireless communication.

The controller 120 may perform a sampling for at least one measurement result generated according to a repeated current measurement. The controller 120 may perform a sampling for measurement result based on the wireless communication transmission period. That is, the controller 120 may compress a total measurement result in response to an amount of transmission that can be transmitted during the wireless communication transmission period. To this end, the controller 120 may extract a minimum value, a maximum value, and an average value for the measurement result. The controller 120 may extract a sample of the number appropriate to the wireless communication transmission period so as to decrease the error of the measurement result.

For instance, when the output period of the analog to digital converter is 200 μs the analog-to-digital converter may convert the output voltage of the amplifier into a digital signal every 200 μs to transmit to the controller 120. The controller 120 may calculate the current based on the transmitted digital signal, and performs a sampling for the calculated current.

For instance, the controller 120 may determine the maximum, minimum and average values with respect to ten currents which are calculated based on ten digital signals outputted from the analog to digital converter during 2 ms. The controller 120 may generate one measurement result based on the determined the maximum, minimum and average values.

When the transmission period of the wireless communication supported by the current measurement apparatus 100 is 10 ms, the controller 120 may form a single data frame with five measurement results to transmit to an external device during the transmission period. Thus, the controller 120 may reduce the amount of data transmission using the wireless communication, and prevent the transmission delay. The storage unit 130 may store a program or a command for the current measurement apparatus 100.

The storage unit 130 may include at least one type of storage medium among a flash memory type, a hard disk type, a multimedia card micro type, a card-type memory (e.g., SD or XD memory, etc.), a Random Access Memory (RAM), a Static Random Access Memory (SRAM), a Read-Only Memory (ROM), an Electrically Erasable Programmable Read-Only Memory (EEPROM), a Programmable Read-Only Memory (PROM), a magnetic memory, a magnetic disk, and an optical disk.

The storage unit 130 may store a first offset, and a second offset. In addition, the storage unit 130 may temporarily or permanently store the voltage transmitted from the measurement circuit unit 110, the current calculated by the controller 120, and the measurement result generated from the controller 120 i.e., the sampling result.

The communication unit 140 may perform a wireless communication with an external device, e.g., a current measurement terminal 200. The communication unit 140 may perform the wireless communication with the external device by using a wireless short distance communication technology such as a Bluetooth communication, an infrared communication, a Near Field Communication (NFC), a Wi-Fi, or the like.

The communication unit 140 may transmit the measurement result including at least one measured current to the external device under the control of the controller 120. At this time, the communication unit 140 may transmit the measurement result sampled by the controller 120 to the external device according to the transmission period of the wireless communication.

Further, the current measurement apparatus 100 may include a power supply unit for supplying a power to the DUT and each component of the current measurement apparatus 100.

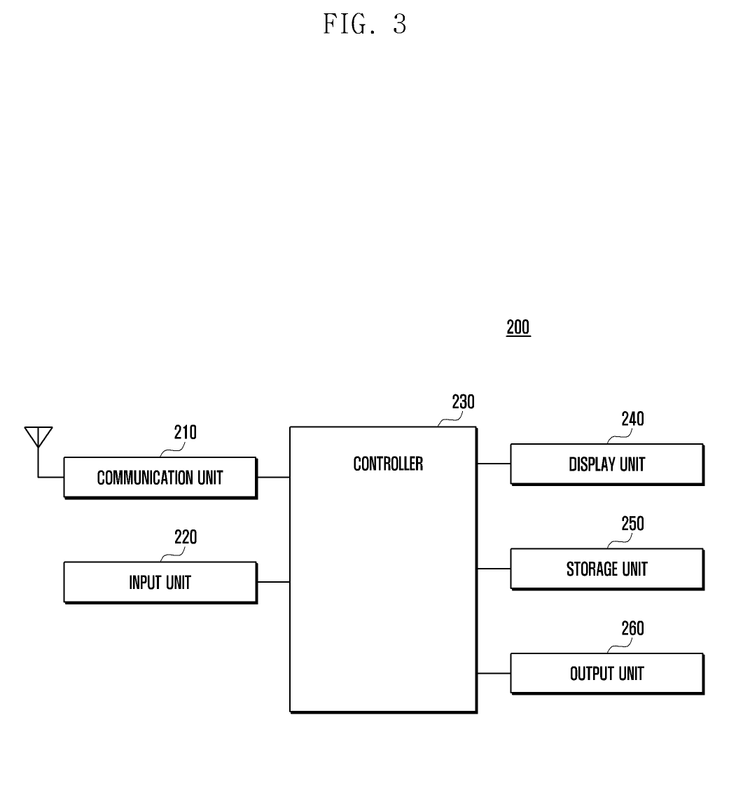

FIG. 3 is a block diagram illustrating a configuration of a current measurement terminal according to an embodiment of the present disclosure.

Referring to FIG. 3, the current measurement terminal 200 may include a communication unit 210, an input unit 220, a controller 230, a display unit 240, a storage unit 250, and an output unit 260.

The communication unit 210 may perform a wireless communication with the outside. The communication unit 210 may include a transmitter for up-converting and amplifying a frequency of a transmitted signal, and a receiver for low-noise amplifying a received signal and down-converting the frequency of the signal, or the like.

According to an embodiment of the present disclosure, the communication unit 210 may perform the wireless communication with the current measurement apparatus 100. The communication unit 210 may perform the wireless communication with the current measurement apparatus 100 by using a wireless short distance communication technology such as a Bluetooth communication, an infrared communication, an NFC, a Wi-Fi, or the like.

The communication unit 210 may receive the measurement result including at least one measured current from the current measurement apparatus 100. At this time, the communication unit 210 may receive the measurement result sampled according to the wireless communication transmission period by the current measurement apparatus 100.

The input unit 220 may detect the input from the user, and transmit an input signal corresponding to the user input to the controller 230. The input unit 220 may include a key pad, a dome switch, a touchpad (capacitive/resistive type), a jog wheel, a jog switch, a finger mouse, a wheel, and the like.

The input unit 220 may include a touch sensor, a proximity sensor, an electromagnetic sensor, a pressure sensor, and the like. The input unit 220 may detect a user's touch input or proximity input through a sensor. The input unit 220 may be implemented with a touch screen by forming a layer structure with the display unit 240 which will be described later.

The input unit 220 may receive a request for the measurement of the current of the DUT, or receive a request for displaying the measurement result.

The controller 230 may control each element to perform the overall operation of the current measurement terminal 200. For instance, the controller 230 may control each element to receive the measurement result from the current measurement apparatus 100, and detect an abnormal current event or output the measurement result. At this time, the current measurement result may include the current value measured based on the voltage compensated by using the voltage offset by the amplifier of the current measurement apparatus 100. The current measurement result may data sampled by the current measurement apparatus 100 in response to the transmission period of the wireless communication.

When the abnormal current event is detected, the controller 230 may store a base station synchronization time in connection with information related to the abnormal current event when the abnormal current event occurs. In addition, the controller 230 may obtain and display a log record of the DUT, or determine and display the number of times of the occurrence of the abnormal current event based on the synchronization time when the abnormal current event occurs.

A more detailed explanation of the operation of the controller 230 will be described in below with reference to drawings.

The display unit 240 may display (output) information processed in the current measurement terminal 200. For instance, the display unit 240 may display the current measurement result of the DUT together with a User Interface (UI) or a Graphic User Interface (GUI).

The display unit 240 may be implemented with a touch screen. The touch screen may perform a function of receiving a user's input for displayed information as well as displaying information.

The touch screen may include a touch panel attached on an image display apparatus by an adhesive layer. The image display apparatus is a device that outputs an image, and may include a Liquid Crystal Display device (LCD), a Plasma Display Panel (PDP), an Electroluminescence (EL) or a Cathode Ray Tube (CRT), or the like. The touch panel may detect a touch coordinate for a user's hand or an input of an object. The touch panel may use various methods, such as a Resistive Type, a Capacitive Type, an Electro Magnetic Type, a Surface Acoustic Wave Type (SAW Type), an Infra Red Type, or the like.

In case of the capacitive type, the touch panel may detect an input by an electronic pen including a conductive material or a coil which can cause electrostatic induction as well as an input by a human body. Further, the touch screen may detect a proximity input within a certain distance from the touch screen.

According to an embodiment of the present disclosure, the display unit 240 may display the measurement result received from the current measurement apparatus 100 under the control of the controller 230. Further, the display unit 240 may display the information related to the occurrence of the abnormal current event based on the measurement result. The display unit 240 may display the log record of the DUT and the number of occurrences at the time of synchronization with the base station when the abnormal current event occurs. The storage unit 250 may store a program or commands for the current measurement terminal 200. The controller 230 may perform the program or the commands stored in the storage unit 250.

The storage unit 250 may include at least one type of storage medium among a flash memory type, a hard disk type, a multimedia card micro type, a card-type memory (e.g., SD or XD memory, etc.), a RAM, a SRAM, a ROM, an EEPROM, a PROM, a magnetic memory, a magnetic disk, and an optical disk.

According to an embodiment of the present disclosure, the storage unit 250 may temporarily or permanently store the measurement result. Further, the storage unit 250 may store the information related to the abnormal current event, the synchronization time with the base station at the time of the occurrence of the abnormal current event, the log record of the measurement terminal, and the number of occurrences.

The output unit 260 may include at least one sound output unit or vibration output unit. The output unit 260 may output a sound or a vibration under the control of the controller 230.

The output unit 260 may notify of the occurrence of the event to a user by outputting the sound or the vibration under the control of the controller 230 when the abnormal current event occurs as a result of the current measurement.

Since the elements shown in FIG. 3 are not essential, the current measurement terminal 200 having more elements or less elements may be implemented.

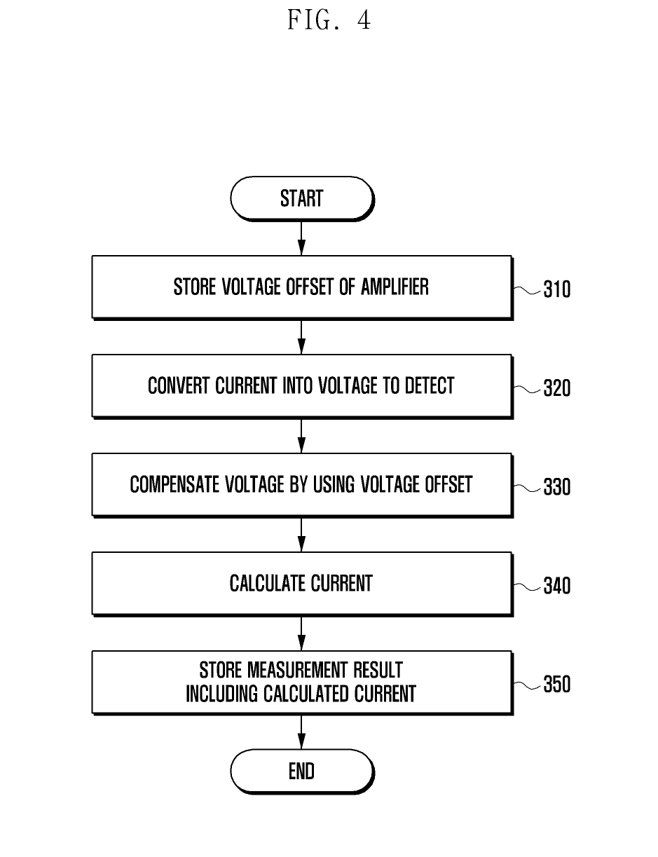

FIG. 4 is a flowchart illustrating a current measurement method of a current measurement apparatus according to an embodiment of the present disclosure.

Referring to FIG. 4, the controller 120 may store the voltage offset of the amplifier at operation 310.

The controller 120 may receive the voltage outputted from the amplifier from the measurement circuit unit 110 when the measurement circuit unit 110 is not connected to the DUT and a current does not flow through a resistor.

The controller 120 may store the received voltage in the storage unit 130 as the amplifier's offset voltage, i.e., the first offset voltage, the first compensation voltage, or the like.

Further, the controller 120 may receive the voltage outputted from the amplifier from the measurement circuit unit 110 when the measurement circuit unit 110 is not connected to the DUT and a reference current (e.g., 1 mA) flows through the resistor. The controller 120 may calculate an error between the received voltage and the theoretical voltage to be measured by the reference current. Further, the controller 120 may store a difference between the error value and the first offset voltage in the storage unit 130 as an offset voltage during operation of the amplifier, i.e., the second offset voltage, the second compensation voltage, or the like.

At operation 320, the controller 120 may convert a current into a voltage and detect the voltage.

The measurement circuit unit 110 may apply the voltage of both ends of the resistor as the input voltage of the amplifier in a state in which the DUT is connected, and transmit the output voltage of the amplifier to the controller 120 such that the controller 120 converts the current of the DUT into a voltage and detect the voltage.

At operation 330, the controller 120 may compensate the voltage by using the voltage offset.

The controller 120 may compensate the voltage detected by the measurement circuit unit 110 by using a pre-stored voltage offset. For instance, the controller 120 may multiply a ratio of the second voltage offset to the reference current used at the time of determining the second voltage offset by the detected voltage. Further, the controller 120 may obtain the finally compensated voltage by subtracting the first voltage offset from the result value of the multiplication.

At operation 340, the controller 120 may calculate the current.

The controller 120 may calculate the current for the DUT based on the compensated voltage. In more detail, the controller 120 may calculate the current of the DUT based on the voltage supplied to the current measurement apparatus 100, the magnitude of the resistor provided in the measurement circuit unit 110, and the received output voltage of the amplifier. For example, the controller 120 may determine the input voltage based on the output voltage by using the characteristic of the amplifier, that is, the voltage measured in the resistor, and may calculate the current of the DUT by using the magnitude of the determined voltage and the resistor.

At operation 350, the controller 120 may store the measurement result including the calculated current.

The controller 120 may store the finally measured current in the storage unit 130 as a measurement result. The controller 120 may measure the current repeatedly until the measurement is terminated, and may store the measurement result.

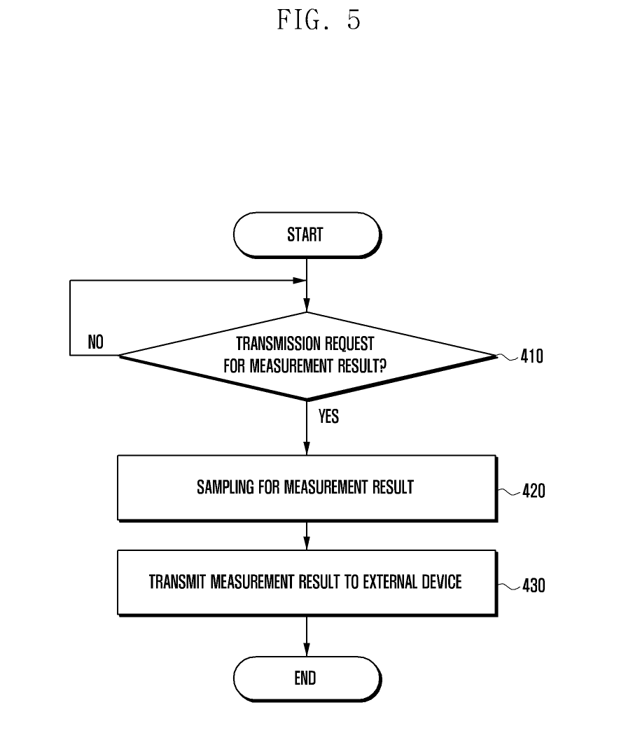

FIG. 5 is a flowchart illustrating a method of transmitting a measurement result to an external device by a current measurement apparatus according to an embodiment of the present disclosure.

Referring to FIG. 5, the controller 120 of the current measurement apparatus 100 may determine whether a transmission request for the measurement result is received at operation 410. The transmission request for the measurement result may occur by an external device, e.g., the current measurement terminal 200, or the like. The controller 120 may receive a wireless signal corresponding to a request message by a wireless communication through the communication unit 140.

In another implementation, the operation of receiving the transmission request for the measurement result may be omitted.

When the transmission request for the measurement result is received, the controller 120 may perform a sampling for the measurement result at operation 420.

The controller 120 may perform the sampling for at least one measurement result generated according to the repetitive current measurement. The controller 120 may perform the sampling for the measurement result based on the wireless communication transmission period. That is, the controller 120 may compress a total measurement result in response to the amount of transmission that can be transmitted during the wireless communication transmission period. To this end, the controller 120 may extract only the minimum, maximum and average values for the measurement result. The controller 120 may extract the sample by the number suitable for the wireless communication transmission period in order to reduce the error of the measurement result.

For instance, when the output period of the analog to digital converter is 200 μs, the analog-to-digital converter may convert the output voltage of the amplifier into a digital signal to transmit to the controller 120 every 200 μs. The controller 120 may calculate the current based on the transmitted digital signal, and perform a sampling for the calculated current. For instance, the controller 120 may determine the maximum, minimum and average values for ten currents calculated based on ten digital signals outputted from the analog to digital converter during 2 ms. The controller 120 may generate one measurement result based on the determined maximum, minimum and average values.

When the transmission period of the wireless communication supported by the current measurement apparatus 100 is 10 ms, the controller 120 may form a single data frame with five measurement results to transmit to an external device during the transmission period. Thus, the controller 120 may reduce the amount of data transmission using the wireless communication, and prevent the transmission delay.

Finally, the controller 120 may transmit the measurement result to the external device at operation 430. The controller 120 may transmit the sampled measurement result to the external device during the wireless communication transmission period.

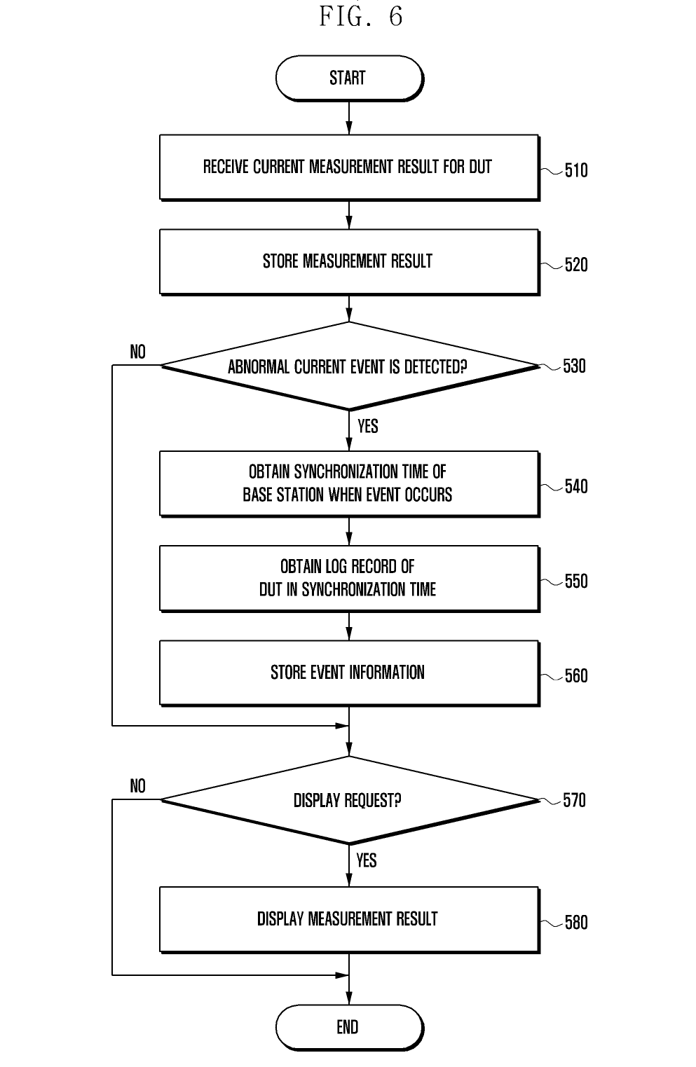

FIG. 6 is a flowchart illustrating a current measurement method of a current measurement terminal according to an embodiment of the present disclosure.

Referring to FIG. 6, the controller 230 of the current measurement terminal 200 may receive the current measurement result for the DUT at operation 510.

The controller 230 may receive the current measurement result from the current measurement apparatus 100 through the communication unit 210. The controller 230 may operate an application for the current measurement according to a request of a user or software, and may control the display unit 240 to display the GUI corresponding to the application.

The controller 230 may receive an input for the DUT and the measurement time through the current measurement application, and may receive an input for requesting the start of the measurement. The controller 230 may transmit a message requesting the current measurement result to the current measurement apparatus 100 according to a request by using a wireless communication. Further, the controller 230 may receive the current measurement result for the DUT from the current measurement apparatus 100 in response to the request message.

At this time, as described in the various embodiments of FIGS. 4 and 5, the measurement result received by the controller 230 may include at least one current value calculated from the voltage compensated by using the amplifier's offset voltage by the current measurement apparatus 100.

In addition, the measurement result received by the controller 230 may be data sampled by the current measurement apparatus 100 based on the wireless communication transmission period. At operation 520, the controller 230 may store the measurement result. The controller 230 may store the received measurement result in the storage unit 250.

At operation 530, the controller 230 may determine whether an abnormal current event is detected. The controller 230 may analyze the received measurement result. The controller 230 may determine whether the abnormal current event is detected based on the maximum, minimum, and average values of the current included in the measurement result.

The abnormal current event may be generated by an abnormal wake up of the terminal. The controller 230 may determine that the abnormal current event occurs when the received measurement result includes a current value higher than a threshold current which is previously set by a user or by a manufacture.

Alternatively, the controller 230 may determine that the abnormal current event occurs when the received measurement result includes a current value corresponding to 90% or more of the preset threshold current.

In an embodiment, when it is determined that the abnormal current event occurs, the controller 230 may output a sound or a vibration through the output unit 260. Alternatively, the controller 230 may display a message, an image, a UI, a GUI, or the like to notify that the abnormal current event occurs through the display unit 240.

Additionally, the controller 230 may count by accumulating the number of occurrences of the abnormal current event. When the abnormal current event is detected, the controller 230 may obtain the synchronization time of the base station when the event occurs at operation 540.

Since each of the current measurement apparatus 100, the DUT, and the current measurement terminal 200 has a separate internal time, the time when the current corresponding to the abnormal current event is measured in the current measurement apparatus 100 may be different from the time when the abnormal current event occurs in the actual DUT.

However, even in such a case, if the DUT and the current measurement terminal 200 are connected to the same base station, then the base station synchronization time of the DUT and the current measurement terminal 200 may be the same. Accordingly, the controller 230 may obtain the base station synchronization time at the time of the occurrence of the abnormal current event so as to determine the accurate time of the occurrence of the abnormal current event. The controller 230 may obtain the synchronization time from the base station, and may obtain the synchronization time by using the internal time of the current measurement terminal 200 when the internal time of the current measurement terminal 200 is synchronized with the base station.

At operation 550, the controller 230 may obtain a log record of the DUT in the synchronization time.

The controller 230 may obtain the log record of the DUT in the synchronization time at the time of the occurrence of the abnormal current event so as to determine the cause of the occurrence of the abnormal current event.

The log record may be received from the DUT or may be received from the base station.

At operation 560, the controller 230 may store the information related to the abnormal current event.

The controller 230 may store the information related to the abnormal current event in connection with the synchronization time and the log record of the DUT into the storage unit 250.

At operation 570, the controller 230 may determine whether a display request occurs.

The controller 230 may determine whether the display request to display the measurement result of the abnormal current of the DUT occurs through the input unit 220.

When the display request occurs, the controller 230 may display the measurement result at operation 580.

The controller 230 may control the display unit 240 to display the stored measurement result. At this time, the controller 230 may also display the information related to the abnormal current event.

According to the mobile current measurement apparatus, the current measurement terminal, and the current measurement method of the present disclosure, the accuracy of the measurement result may be enhanced without the increase of price or the increase of equipment size.

Further, according to the mobile current measurement apparatus, the current measurement terminal, and the current measurement method of the present disclosure, the measurement result may be wirelessly transmitted by sampling the measurement result, such that the efficiency of the wirelessly transmission may be enhanced, and the measurement result can be easily checked in another terminal by enhancing mobility.

Further, according to the mobile current measurement apparatus, the current measurement terminal, and the current measurement method of the present disclosure, the abnormal current may be efficiently monitored to perform a quick debugging for the device-under-test.

While the present disclosure has been shown and described with reference to various embodiments thereof, it will be understood by those skilled in the art that various changes in form and details may be made therein without departing from the spirit and scope of the present disclosure, as defined by the appended claims and their equivalents.

What is claimed is:

1. A method of measuring a current by a current measurement apparatus, the method comprising:
detecting a voltage converted from a current of a device-under-test;
compensating the detected voltage by using a voltage offset generated by an amplifier of the current measurement apparatus; and
measuring the current of the device-under-test based on the compensated voltage.

2. The method of claim 1, wherein the compensating of the detected voltage comprises compensating the detected voltage by using an output voltage of the amplifier when no current flows in a resistor connected between both ends of the amplifier of the current measurement apparatus.

3. The method of claim 2, wherein the compensating of the detected voltage comprises compensating the detected voltage by using the output voltage of the amplifier when a reference current flows in the resistor.

4. The method of claim 1, further comprising transmitting a measurement result including the measured current to an external device by using a wireless communication.

5. The method of claim 4, wherein the transmitting of the measurement result comprises:
performing a sampling for at least one measured current according to a transmission period of the wireless communication; and
transmitting the at least one sampled measured current to the external device.

6. A method of measuring a current, the method comprising:
detecting a request for measuring a current of a device-under-test;
receiving a current measurement result for the device-under-test from a current measurement apparatus in response to the request; and
displaying the received current measurement result.

7. The method of claim 6, further comprising:
determining whether an abnormal current event occurs based on the current measurement result; and
storing a base station synchronization time at a time of an occurrence of the abnormal current event in connection with information related to the abnormal current event when the abnormal current event occurs.

8. The method of claim 7, further comprising:
receiving a log record of the device-under-test in the base station synchronization time; and
displaying the log record.

9. The method of claim 6, wherein the current measurement result includes a current value measured based on a voltage compensated by using a voltage offset by an amplifier of the current measurement apparatus

10. The method of claim 6, wherein the receiving of the current measurement result comprises receiving at least one measured current sampled in response to a transmission period of wireless communication.

11. A current measurement apparatus comprising:
a measurement circuit unit configured to detect a voltage converted from a current of a device-under-test;
a controller configured to compensate the detected voltage by using a voltage offset generated by an amplifier of the current measurement apparatus, and measure the current of the device-under-test based on the compensated voltage; and
a storage unit configured to store the measured current under control of the controller.

12. The current measurement apparatus of claim 11, wherein the measurement circuit unit comprises a resistor connected to an amplifier and connected between both ends of the amplifier, and the controller compensates the voltage detected by the measurement circuit unit by using an output voltage of the amplifier when no current flows in the resistor.

13. The current measurement apparatus of claim 12, wherein the controller compensates the voltage detected by the measurement circuit unit by using the output voltage of the amplifier when a reference current flows in the resistor.

14. The current measurement apparatus of claim 11, further comprising a communication unit to perform a wireless communication with an external device, wherein the controller controls the communication unit to transmit a measurement result including the measured current to the external device by using the wireless communication.

15. The current measurement apparatus of claim 14, wherein the controller performs a sampling for at least one measured current according to a transmission period of the wireless communication, and controls to transmit the at least one sampled measured current to the external device.

16. A current measurement terminal comprising:
a communication unit configured to perform a wireless communication with a current measurement apparatus;
a display unit configured to output data; and
a controller configured to control the communication unit to receive a current measurement result for a device-under-test from the current measurement apparatus, and control the display unit to display the received current measurement result.

17. The current measurement terminal of claim 16, further comprising a storage unit configured to store data, wherein the controller determines whether an abnormal current event occurs based on the current measurement result, and stores a base station synchronization time at a time of an occurrence of the abnormal current event in connection with information related to the abnormal current event into the storage unit, when the abnormal current event occurs.

18. The current measurement terminal of claim 17, wherein the controller controls the communication unit to receive a log record of the device-under-test in the base station synchronization time, and controls the display unit to display the log record.

19. The current measurement terminal of claim 16, wherein the current measurement result includes a current value measured based on a voltage compensated by using a voltage offset by an amplifier of the current measurement apparatus

20. The current measurement terminal of claim 16, wherein the communication unit receives at least one measured current sampled in response to a transmission period of the wireless communication.
